(19) United States
(12) Patent Application Publication
(10) Pub. No.: US 2013/0001637 A1
(43) Pub. Date: Jan. 3, 2013

(54) NITRIDE SEMICONDUCTOR LIGHT-EMITTING DEVICE

(75) Inventor: Mayuko FUDETA, Osaka-shi (JP)

(73) Assignee: SHARP KABUSHIKI KAISHA, Osaka-shi (JP)

(21) Appl. No.: 13/535,000

(22) Filed: Jun. 27, 2012

(30) Foreign Application Priority Data
Jun. 30, 2011 (JP) 2011-145906

(51) Int. Cl. H01L 33/26

(52) U.S. Cl. 257/103; 257/E33.013

(57) ABSTRACT

A nitride semiconductor light-emitting device has an n-type nitride semiconductor layer, a lower light-emitting layer, an upper light-emitting layer, and a p-type nitride semiconductor layer in this order. The lower light-emitting layer is formed by alternately stacking a plurality of lower well layers, and a lower barrier layer sandwiched between the lower well layers and having a large bandgap than the lower well layer. The upper light-emitting layer is formed by alternately stacking a plurality of upper well layers, and an upper barrier layer sandwiched between the upper well layers and having a larger bandgap than the upper well layer. Thickness of the upper barrier layer in the upper light-emitting layer is smaller than thickness of the lower barrier layer in the lower light-emitting layer.

This nonprovisional application is based on Japanese Patent Application No. 2011-145906 filed on Jun. 30, 2011with the Japan Patent Office, the entire contents of which are hereby incorporated by reference.

### BACKGROUND OF THE INVENTION

1. Field of the Invention

The present invention relates to a nitride semiconductor light-emitting device.

2. Description of the Background Art

A III-V group compound semiconductor containing nitrogen (hereinafter, referred to as “nitride semiconductor”) has a bandgap corresponding to the energy of light having a wavelength in the infrared region to the ultraviolet region, so that it is useful as a material for a light-emitting device that emits light having a wavelength in the infrared region to the ultraviolet region or a material for a light-receiving device that receives light having a wavelength in the infrared region to the ultraviolet region.

Further, a nitride semiconductor is useful as a material for an electronic device such as a high temperature-resistant, high-output and high-frequency transistor because binding between atoms constituting the nitride semiconductor is strong, and dielectric breakdown voltage is high, and a saturation electron velocity is high.

Further, the nitride semiconductor will rarely harm the environment, and attracts attention as an easily-handled material.

In a nitride semiconductor light-emitting device using such a nitride semiconductor, a quantum well structure is generally employed as a light-emitting layer. When a voltage is applied, an electron and a hole are recombined in a well layer in the light-emitting layer, and as a result, light is generated. The light-emitting layer may have a single quantum well structure, or may have a multiple quantum well structure where a well layer and a barrier layer are alternately stacked.

Japanese Patent Laying-Open No. 2005-109425 describes that an active layer (corresponding to a light-emitting layer in the present application) is formed by sequentially stacking an undoped GaN barrier layer and an InGaN quantum well layer doped with an n-type impurity (corresponding to a dopant in the present application). Also the publication describes that the undoped GaN barrier layer has a diffusion preventive film at the interface where it is in contact with the aforementioned InGaN quantum well layer, and that the diffusion preventive film contains an n-type impurity at a concentration lower than that in the InGaN quantum well layer.

Japanese Patent Laying-Open No. 2000-349337 describes that an active layer contains an n-type impurity, and that concentration of the n-type impurity in the active layer is higher in the n layer side than in the p layer side. The publication also describes that since concentration of the n-type impurity in the active layer is higher in the n layer side than in the p layer side, supply of a donor from the n-layer side to the active layer can be compensated, and a nitride semiconductor device having high light emission output can be obtained.

Japanese Patent Laying-Open No. 2007-150312 describes that excellent light output power is obtained by setting thickness of a barrier layer to greater than or equal to 13 times thickness of a well layer in a quantum well active layer.

Recently, as use application of a nitride semiconductor light-emitting device, a backlight for liquid crystal and an electric bulb for illumination are considered, and the case where a nitride semiconductor light-emitting device is driven at a large current is on the increase.

Japanese Patent Laying-Open No. 2007-067418 describes a technique for improving characteristics at the time of driving at a large drive current by employing a single well layer thicker than that of a conventional case as an active layer having an active layer thickness ranging from 50 angstroms to 250 angstroms, against the background that “A commercially available III group nitride device having an InGaN light-emitting layer often has a plurality of quantum well light-emitting layers that have a thickness of less than 50 angstroms and are typically doped at less than about 1×10¹⁸ cm⁻³. This is because such a quantum well design can improve the performance of a low-quality epitaxial material particularly at a low drive current. At a high derive current desired for illumination, efficiency of such a device decreases as the current density increases”.

### SUMMARY OF THE INVENTION

When a nitride semiconductor light-emitting device is produced according to the conventional techniques, and the produced nitride semiconductor light-emitting device is driven at a large current, the operation voltage can rise to lead increase in power consumption, and deterioration in light emission efficiency can be incurred. From this, deterioration in light emission efficiency per unit power (power efficiency) can also be incurred.

In general, light emission efficiency decreases when the current density applied to the nitride semiconductor light-emitting device is relatively lower or high. It is believed that decrease in light emission efficiency at a relatively low current density ascribes to a number of levels (crystal defect and so on) existing in the light-emitting layer, the levels inducing non-light-emitting recombination. For this reason, a conventional measure for improving the light emission efficiency of a nitride semiconductor light-emitting device is principally reduction of crystal defects in the light-emitting layer.

However, when the current density applied to the nitride semiconductor light-emitting device increases, light emission efficiency is reduced due to a factor other than a crystal defect in the light-emitting layer. As such a factor, an Auger recombination theory, a piezoelectric filed theory, an overflow theory and the like are proposed.

The Auger recombination theory is such that one cause of decrease in light emission efficiency at a large current density is that Auger recombination (non-light-emitting recombination where probability of recombination increases in proportional to the cube of the density of injected carriers) is dominant as the density of injected carriers in the active layer increases.

The piezoelectric field theory is as follows. When composition of a well layer is InₓGa₁₋ₓN and composition of a barrier layer is GaN, the lattice constant is different between these so that the lattice having originally a square-shaped cross section is extended or compressed into a rectangular shape. In association with this, “piezoelectric field” arises in crystal, especially in a well layer, and owing to the influence of the same, inclination arises in energy bands (valence band, conduction band) of the semiconductor, and the positions where the density distributions of holes and electrons peak are spatially separated on the opposite sides of the well layer. As a result, light-emitting recombination between an electron and a hole is prevented (lifetime of light-emitting recombination is prolonged).

The overflow theory is such that when injection of electrons into a light-emitting layer is increased, electrons overflow from the light-emitting layer to reach a p-side layer where they disappear by non-light-emitting recombination.

In any of these theories, it is desired to lower the density of injected carries in the well layer, or in other words, to increase the volume of the well layer for suppressing decrease in light emission efficiency at the time of driving at a large current.

As a measure for decreasing the injected carrier density in the active layer, a method of making the chip size larger to increase the light emission area and decrease the current value per unit area, thereby decreasing the density of the carriers that are actually injected per unit volume can be supposed. However, when the chip size is made larger, the number of chips that can be produced from one wafer is also decreased, and increase in cost of the nitride semiconductor light-emitting device will be incurred.

As another measure for decreasing the density of injected carriers in the active layer, a method of increasing the thickness of well layer in a multiple quantum well structure, and a method of increasing the number of layers of well layer can be supposed. However, when the thickness of well layer is too large, deterioration in crystal quality of the well layer will be incurred. Also, when the number of layers of well layer is too large, increase in operation voltage of the nitride semiconductor light-emitting device will be incurred. Further, if the density distribution differs between the injected electrons and holes, even when the apparent volume of the well layer increases, the effective volume of the well layer will not increase in proportional to the same.

The invention was devised in consideration of this point, and it is an object of the present invention to produce a nitride semiconductor light-emitting device capable of preventing deterioration in crystal quality of the light-emitting layer and of preventing increase in operation voltage and deterioration in light emission efficiency even when it is driven at a large current, and hence realizing excellent power efficiency.

A nitride semiconductor light-emitting device according to the present invention has an n-type nitride semiconductor layer, a lower light-emitting layer, an upper light-emitting layer, and a p-type nitride semiconductor layer in this order. The lower light-emitting layer is formed by alternately stacking a plurality of lower well layers and a lower barrier layer sandwiched between the lower well layers, and having a large bandgap than the lower well layer. The upper light-emitting layer is formed by alternately stacking a plurality of upper well layers, and an upper barrier layer sandwiched between the upper well layers and having a larger bandgap than the upper well layer. Thickness of the upper barrier layer in the upper light-emitting layer is smaller than thickness of the lower barrier layer in the lower light-emitting layer.

This constitution was derived from the idea of making the part where thickness of the barrier layer is small in the upper light-emitting layer function as a main light-emitting layer, and making the part where thickness of the barrier layer is large in the lower light-emitting layer function as a crystal recovery layer.

Since a light-emitting layer of a nitride semiconductor light-emitting device generally includes a well layer made of In_{z}Ga_{1-z}N (z>0), growth temperature of the light-emitting layer is lower than growth temperature of a nitride semiconductor layer of GaN, AlGaN or the like not containing In. When crystal is grown by a MOCVD (Metal Organic Chemical Vapor Deposition) method, nitrogen is used as a large part of the carrier gas, and no or otherwise a slight amount of hydrogen is used. For such a growth condition, a crystal defect is likely to occur in the light-emitting layer.

For improving the light emission efficiency with least influenced by a crystal defect existing in the light-emitting layer even when such a crystal defect exists in the light-emitting layer, it is necessary that light-emitting recombination occurs before an injected carrier is captured by the crystal defect, and for this, it is necessary to decrease the inclination of the band by the piezoelectric field in the well layer. However, in the case of a general structure that nitride semiconductor crystals are grown in the c axis direction using a sapphire substrate having a surface of C face, and a majority of nitride semiconductor crystals are formed of GaN, and an In_{z}Ga_{1-z}N (z>0) well layer having a different lattice constant is provided therein to cause light emission in the well layer, a piezoelectric field necessarily arises in the well layer due to difference in lattice constant between the well layer and other nitride semiconductor layer than the well layer. In the present example, the inventor reached the idea of thinning the barrier layer in the upper light-emitting layer where contribution to light emission is particularly large for decreasing the piezoelectric field in the well layer.

The present inventor supposes that only by thinning the barrier layer, difference in composition of the barrier layer from the average composition of the barrier layer and the well layer is reduced, so that the piezoelectric field in the well layer can be reduced. Also, since a crystal defect increases as the barrier layer is thinned in the entire light-emitting layer, only a barrier layer of the p-layer side light-emitting layer dominantly emitting light in the light-emitting layer is thinned to reduce the piezoelectric field, and in the n-layer side light-emitting layer, the barrier layer was thickened by attaching great importance to the effect of reducing the crystal defects accumulated after growth of the well layer in the barrier layer. The barrier layer does not contain In, or has lower In composition than the well layer even when the barrier layer contains In. Therefore, it is easier to improve the crystal quality of the barrier layer than to improve the crystal quality of the well layer. Therefore, we supposes that by growing the bather layer in the n-layer side light-emitting layer thickly, the function of recovering the crystal quality deteriorated in the well layer is carried out.

Although it seems to be desirable to eliminate the well layer from the lower light-emitting layer and to provide only the barrier layer considering just the crystal quality, it is actually expected that the lower light-emitting layer has an effect of relaxing strain. Therefore, for reducing the piezoelectric field of the upper light-emitting layer, it is preferred that the lower light-emitting layer includes the well layer.

Also the inventor supposes that the following effects are obtained by thinning the barrier layer in the upper light-emitting layer. Since diffusion of holes injected from the p-layer side into the entire light-emitting layer is not sufficient in the light-emitting layer, the hole density is higher in the well layer closer to the p layer, and the hole density decreases as the well layer is farther from the p layer. For diffusing the holes to lower well layers, it can be expected to decrease the thickness of the barrier layer provided between well layers, and to shorten the distance to the lower well layers. On the other hand, since holes are difficult to reach the lower light-emitting layer less functioning as a light-emitting layer even when the barrier layer is thinned, the barrier layer of that part is thickened by attaching great importance to the function as a crystal recovery layer. In this manner, it is possible to improve the crystal quality and light emission efficiency in the upper light-emitting layer.

Preferably, thickness of the upper barrier layer is smaller than thickness of the lower barrier layer by greater than or equal to 0.5 nm.

Preferably, thickness of each layer of the lower barrier layer and the upper barrier layer is equal to thickness of a directly under layer, or decreases toward the p-type nitride semiconductor layer. Here, the “directly under layer” means a lower barrier layer situated on the side of the n-type nitride semiconductor with one layer of the lower well layer interposed therebetween with respect to the lower barrier layer of interest, and means an upper barrier layer situated on the side of the n-type nitride semiconductor with one layer of the upper well layer interposed therebetween with respect to the upper barrier layer of interest.

Preferably, average n-type doping concentration of the lower light-emitting layer is higher than average n-type doping concentration of the upper light-emitting layer.

Since the lower light-emitting layer serves also as an n-type carrier injection layer of the upper light-emitting layer, by making average n-type doping concentration of the lower light-emitting layer higher than average n-type doping concentration of the upper light-emitting layer, an electron becomes easy to migrate, electric resistance at that part decreases, and the drive voltage can be reduced.

Preferably, average n-type doping concentration of each layer of the lower barrier layer and the upper barrier layer is equal to average n-type doping concentration of a directly under layer, or decreases toward the p-type nitride semiconductor layer. Here, the “directly under layer” is as defined in the above.

According to the nitride semiconductor light-emitting device of the present invention, even when it is driven at a large current, increase in operation voltage is prevented, and decrease in light emission efficiency is prevented, and accordingly, excellent power efficiency is realized.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic sectional view of a nitride semiconductor light-emitting device according to one embodiment of the present invention.

FIG. 2 is a schematic plan view of the nitride semiconductor light-emitting device according to one embodiment of the present invention.

FIG. 3 is an energy chart schematically showing the magnitude of band gap energy Eg in a nitride semiconductor layer forming the nitride semiconductor light-emitting device according to one embodiment of the present invention.

FIG. 4 is a graph showing a result of Example 1.

### DESCRIPTION OF THE PREFERRED EMBODIMENTS

In the following, embodiments of the present invention will be described with reference to drawings.

In the following, “barrier layer” indicates a layer sandwiched between well layers, and a layer that is not sandwiched between well layers is indicated by “first barrier layer” or “last barrier layer” different from layers sandwiched between well layers. This is because migration of a hole or an electron in a barrier layer formed between well layers is particularly important in the present invention.

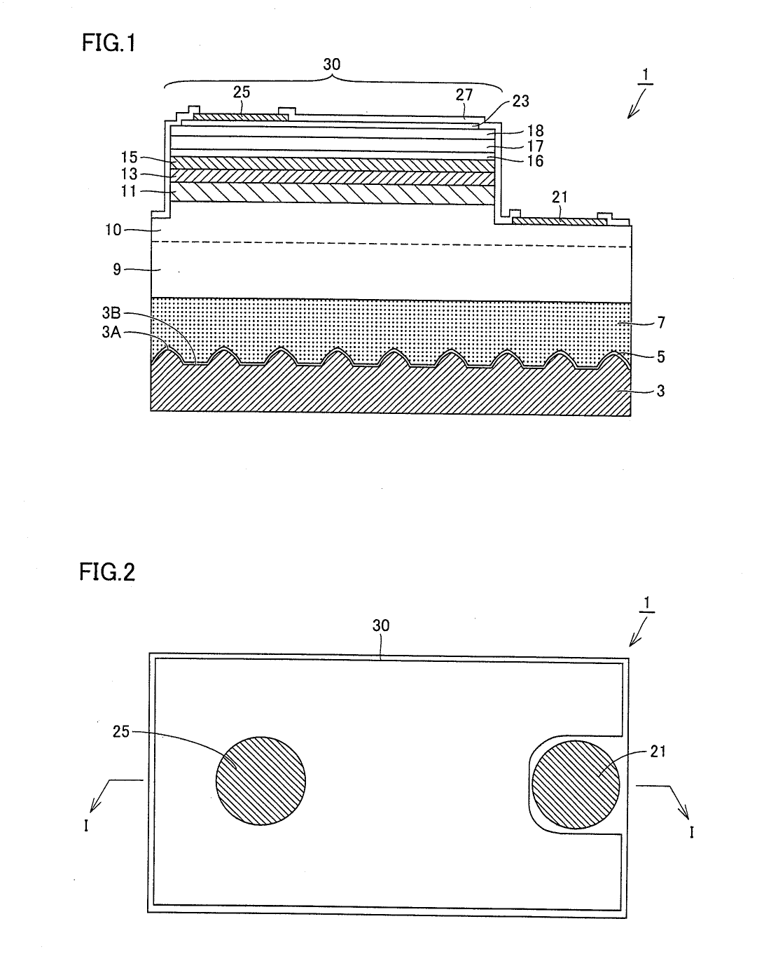

In the following embodiments, representations “lower light-emitting layer” and “upper light-emitting layer” are used, however, the expression “lower light-emitting layer” is used for convenience for indicating a layer closer to the n-side nitride semiconductor layer, and the expression “upper light-emitting layer” is used for convenience for indicating a layer closer to the p-side nitride semiconductor layer. For example, the representations “lower light-emitting layer” and “upper light-emitting layer” are not changed even when FIG. 1 is turned upside down, for example. A substrate may be formed on “upper light-emitting layer”, or a substrate may be peeled off to form a nitride semiconductor light-emitting device not having a substrate.

In the following, the term “carrier concentration” and the term “doping concentration” are used, and the relation between these will be described later.

The present invention will not be limited to the following embodiments. Further, in the drawings of the present invention, length, width, thickness and the like dimensional relationships are appropriately modified for clarification and simplification of the drawings, and do not represent actual dimensional relationships.

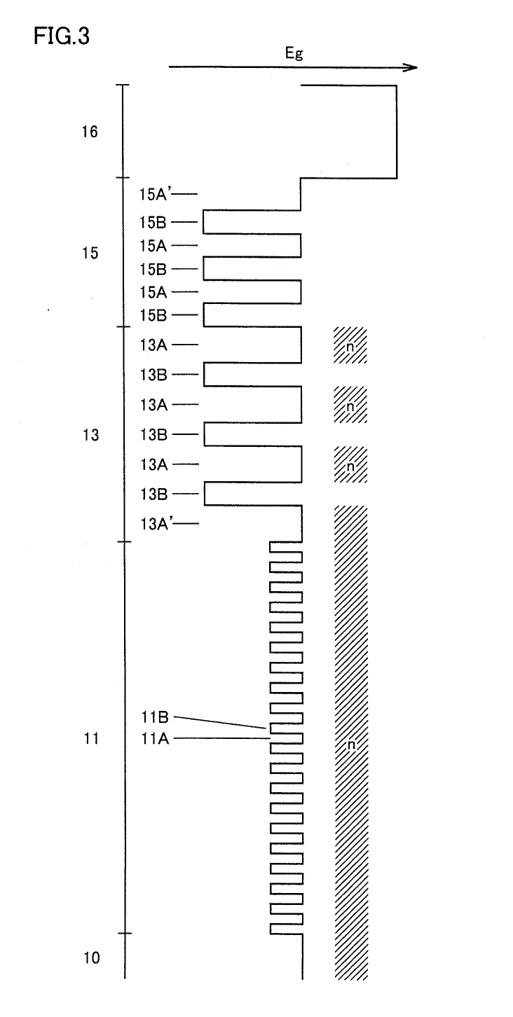

FIG. 1 and FIG. 2 respectively show a schematic sectional view and a schematic plan view of a nitride semiconductor light-emitting device I according to an embodiment of the present invention. A sectional view along the line I-I shown in FIG. 2 corresponds to FIG. 1. Also, FIG. 3 is an energy chart schematically showing the magnitude of bandgap energy Eg from superlattice layer 11 to p-type nitride semiconductor layer 16 in nitride semiconductor light-emitting device 1 shown in FIG. 1. The vertical direction in FIG. 3 is the up and down direction of the layer shown in FIG. 1, Eg of the horizontal axis in FIG. 3 schematically represents the magnitude of bandgap energy in each composition. In FIG. 3, the layers subjected to n-type doping are shaded.

<Nitride Semiconductor Light-Emitting Device>

In nitride semiconductor light-emitting device 1 according to the present embodiment, on an upper face of substrate 3, a buffer layer 5, a base layer 7, n-type nitride semiconductor layers 9, 10, a superlattice layer 11, a lower light-emitting layer 13, an upper light-emitting layer 15, and p-type nitride semiconductor layers 16, 17, 18 are sequentially stacked in this order to form a mesa part 30 (see FIG. 2). A part of an upper face of n-type nitride semiconductor layer 10 is not covered with superlattice layer 11 and exposed, and on this exposed part, an n-side electrode 21 is provided. On p-type nitride semiconductor layer 18, a p-side electrode 25 is provided with a transparent electrode 23 interposed therebetween. Almost whole of the upper face of nitride semiconductor light-emitting device 1 is provided with a transparent protection film 27 so that p-side electrode 25 and n-side electrode 21 are exposed.

<Substrate>

Substrate 3 may be an insulating substrate made, for example, of sapphire or the like, or may be a conductive substrate made of GaN, SiC, ZnO or the like. While thickness of substrate 3 is set at 120 μm, the thickness is not particularly limited to this, and may be for example, greater than or equal to 50 μm and less than or equal to 300 μm. The upper face of substrate 3 may be flat or may have a convexoconcave shape made up of a projecting portion 3A and a recess portion 3B as shown in FIG. 1.

<Buffer Layer>

Buffer layer 5 is preferably, for example, an Alₛ₀Gaₜ₀N (0≦s0≦1, 0≦t0≦1, s0+t0≠0) layer, and more preferably an AlN layer. A small part (0.5 to 2%) of N may be substituted by oxygen. As a result, buffer layer 5 is formed to extend in the normal direction of the growth face of substrate 3, and hence buffer layer 5 made up of an assembly of columnar crystals having uniform crystal grains is obtained.

Thickness of buffer layer 5 is not particularly limited, and is preferably greater than or equal to 3 nm and less than or equal to 100 nm, and more preferably greater than or equal to 5 nm and less than or equal to 50 nm.

### <Base Layer>

Base layer 7 is preferably, for example, an Alₛ₁Gaₜ₁Inᵤ₁N (0≦s1≦1, 0≦t1≦1, 0≦u1≦1, s1+t1+u1≠0) layer, and more preferably an Alₛ₁Gaₜ₁N (0≦s1≦1, 0≦t1≦1, s1+t1≠0) layer, and further preferably a GaN layer. As a result, a crystal defect (such as dislocation or the like) existing in buffer layer 5 is more likely to be looped near the interface between buffer layer 5 and base layer 7, and hence it is possible to prevent the crystal defect from being taken over to base layer 7 from buffer layer 5.

Base layer 7 may contain an n-type impurity. However, when base layer 7 does not contain an n-type impurity, excellent crystallinity of base layer 7 can be maintained. Therefore, it is preferred that base layer 7 does not contain an n-type impurity.

By increasing thickness of base layer 7, defects in base layer 7 are reduced; however, the effect of reducing defects in base layer 7 is saturated even when thickness of base layer 7 is increased over a certain degree. From this, thickness of base layer 7 is preferably, but not particularly limited to, greater than or equal to 1 μm and less than or equal to 8 μm.

<N-Type Nitride Semiconductor Layer>

N-type nitride semiconductor layers 9, 10 are preferably, for example, an Alₛ₂Gaₜ₂Inᵤ₂N (0≦s2≦1, 0≦t2≦1, 0≦u2≦1, s2+t2+u2≠1) layer doped with an n-type impurity, and more preferably an Alₛ₂Ga₁₋ₛ₂N (0≦s2≦1, preferably 0≦s2≦0.5, more preferably 0≦s2≦0.1) layer doped with an n-type impurity.

The n-type dopant is not particularly limited, and is preferably Si, P, As, Sb or the like, and more preferably Si. This also applies in later-described individual layers.

Concentration of the n-type dopant in n-type nitride semiconductor layers 9, 10 is not particularly limited, and is preferably less than or equal to 1×10¹⁷ cm⁻³.

The larger the thicknesses of n-type nitride semiconductor layers 9, 10, the more the resistances thereof reduce. Therefore, thicknesses of n-type nitride semiconductor layers 9, 10 are preferably larger. However, as thickness of n-type nitride semiconductor layers 9, 10 increase, the cost rises. Therefore, practically, smaller thicknesses of n-type nitride semiconductor layers 9, 10 are preferred. Thicknesses of n-type nitride semiconductor layers 9, 10 are preferably, but not particularly limited to, greater than or equal to 1 μm and less than or equal to 10 μm from the practical standpoint.

N-type nitride semiconductor layers 9, 10 are formed in two growing steps by once interrupting growth of the same n-type GaN layer in later-described Example 1, and n-type nitride semiconductor layer 9 and n-type nitride semiconductor layer 10 may be successive to form a monolayer, or have a laminated structure made up of three or more layers. The individual layers may have the same composition, or different compositions. Also, the individual layers may have the same film thickness or different film thicknesses.

<Superlattice Layer>

The superlattice layer in this specification means a layer made up of a crystal lattice having a periodical structure longer than that of a basic unit lattice by alternately stacking very thin crystal layers. As shown in FIG. 3, in superlattice layer 11, a wide bandgap layer 11A and a narrow bandgap layer 11B are alternately stacked to form a superlattice structure, and its periodical structure is longer than a basic unit lattice of the semiconductor material forming wide bandgap layer 11A and a basic unit lattice of the semiconductor material forming narrow bandgap layer 11B. Here, superlattice layer 11 may form a superlattice structure by alternately stacking one or more layer of semiconductor layer other than wide bandgap layer 11A and narrow bandgap layer 11B, wide bandgap layer 11A, and narrow bandgap layer 11B sequentially. Also, thickness per one period of superlattice layer 11 (the sum of layer thickness of wide bandgap layer 11A and layer thickness of narrow bandgap layer 11B) is smaller than thickness per one period of later-described lower light-emitting layer 13, and concretely preferably greater than or equal to 1 nm and less than or equal to 10 nm.

Each wide bandgap layer 11A is preferably, for example, an AlₐGa_{b}In_{(1-a-b)}N (0≦a<1, 0<b≦1) layer, and more preferably a GaN layer.

Composition of each narrow bandgap layer 11B is preferably, for example, AlₐGa_{b}In_{1-a-b)}N (0≦a<1, 0<b≦1) having a bandgap energy that is smaller than that of wide bandgap layer 11A, and is larger than respective bandgap energies of later-described lower well layer 13B and upper well layer 15B, and more preferably Ga_{b}In_{(1-b)}N (0<b≦1).

Preferably, at least one of each wide bandgap layer 11A and each narrow bandgap layer 11B contains an n-type dopant. This is because a drive voltage increases if both wide bandgap layer 11A and narrow bandgap layer 11B are undoped.

Respective number of layers of wide bandgap layer 11A and narrow bandgap layer 11B may be for example, 2 to 50 although 20 is shown in FIG. 3.

Superlattice layer 11 is provided for reducing crystal defects such as threading dislocation existing in n-type nitride semiconductor layers 9, 10, and for reducing crystal defects in lower light-emitting layer 13 and upper light-emitting layer 15. However, when there are few crystal defects, and when lower light-emitting layer 13 is designed to have a function of reducing crystal defects of superlattice layer 11 as well, the superlattice layer 11 can be omitted.

<Lower Light-Emitting Layer>

As shown in FIG. 3, lower light-emitting layer 13 has such a constitution that lower barrier layer 13A is sandwiched between lower well layers 13B by stacking lower well layer 13B and lower barrier layer 13A alternately, and is provided on superlattice layer 11 with first lower barrier layer 13A′ interposed therebetween. Bandgap energy of lower barrier layer 13A is larger than bandgap energy of lower well layer 13B. Similarly to superlattice layer 11, lower light-emitting layer 13 may be formed by sequentially stacking one or more layer of semiconductor layer that is different from lower barrier layer 13A and lower well layer 13B, lower barrier layer 13A, and lower well layer 13B. Preferably, length of one period of lower light-emitting layer 13 (a total thickness of lower barrier layer 13A and lower well layer 13B) is, for example, greater than or equal to 5 nm and less than or equal to 100 nm.

Composition of each lower well layer 13B is preferably adjusted in accordance with the emission wavelength required for the nitride semiconductor light-emitting device according to the present embodiment, and is, for example, preferably AlₐGa_{b}In_{(1-a-b)}N (0≦a<1, 0<b≦1), and more preferably an In_{c}Ga_{(1-c)}N (0<c≦1) layer not containing Al. However, when ultraviolet emission, for example, at less than or equal to 375 nm is conducted, Al is generally contained as appropriate so as to widen the band gap.

Each of lower barrier layer 13A and first lower barrier layer 13A′ is for example, preferably an AlₐGa_{b}In_{(1-a-b)}N (0≦a<1, 0<b≦1) layer, and more preferably a GaN layer. However, since it is necessary to make bandgap energy of lower barrier layer 13A larger than that of lower well layer 13B, the bandgap energy is adjusted by appropriately introducing In, Al, or In and Al.

Average n-type doping concentration of lower light-emitting layer 13 is preferably higher than average n-type doping concentration of later-described upper light-emitting layer 15. As a result, even when nitride semiconductor light-emitting device 1 is driven at a large current, rise in the drive voltage is suppressed, and decrease in power efficiency can be prevented. However, if rise in the drive voltage can be suppressed by other measure, it will be preferred that average n-type doping concentration of lower light-emitting layer 13 is lower than average n-type doping concentration of upper light-emitting layer 15 because light emission efficiency is improved.

From the view point of suppressing rise in drive voltage, it is preferred that each lower well layer 13B and at least one barrier layer of each lower barrier layer 13A and first lower barrier layer 13A′ contain an n-type dopant. It is more preferred that n-type doping concentration of each lower barrier layer 13A is higher than n-type doping concentration of each lower well layer 13B.

N-type doping concentration in each lower well layer 13B and each lower barrier layer 13A is preferably greater than or equal to 1×10¹⁷ cm⁻³, and more preferably greater than or equal to 3×10¹⁷ cm⁻³ and less than or equal to 3×10¹⁰ cm⁻³ without limited to these. When average carrier concentration of lower light-emitting layer 13 (substantially equal to n-type doping concentration when dopant is Si) is less than 1×10¹⁷ cm⁻³, the drive voltage of nitride semiconductor light-emitting device 1 tends to rise. Thickness of each lower well layer 13B is preferably, but not particularly limited to, greater than or equal to 1.5 nm and less than or equal to 5.5 nm. When thickness of each lower well layer 13B is outside this range, light emission efficiency can decrease.

Thickness of each lower barrier layer 13A and first lower barrier layer 13A′ is preferably greater than or equal to 3 nm, and is further preferably greater than or equal to 4 nm and less than or equal to 20 nm without particularly limited to these. Thickness of each lower barrier layer 13A is not necessarily uniform, and in particular, thickness of first lower barrier layer 13A′ shown in FIG. 3 may be different from thickness of each lower barrier layer 13A.

Generally, in a nitride semiconductor light-emitting device, difference in lattice constant or the like between a well layer and an n-type nitride semiconductor layer forming a light-emitting layer leads occurrence of strain, and lower light-emitting layer 13 serves to reduce crystal defects caused by this strain.

<Upper Light-Emitting Layer>

Upper light-emitting layer 15 is formed in such a manner than upper barrier layer 15A is sandwiched between upper well layers 15B by alternately stacking upper well layer 15B and upper barrier layer 15A as shown in FIG. 3, and on upper well layer 15B at the position nearest to p-type nitride semiconductor layer 16 of upper well layers 15B, last upper barrier layer 15A′ is provided. Bandgap energy of upper barrier layer 15A and last upper barrier layer 15A′ is larger than bandgap energy of upper well layer 15B. Upper light-emitting layer 15 may be formed by sequentially stacking one or more layer of semiconductor layer that is different from upper barrier layer 15A and upper well layer 15B, upper barrier layer 15A, and upper well layer 15B. Length of one period of upper light-emitting layer 15 (the sum of thickness of upper barrier layer 15A and thickness of upper well layer 15B) is preferably greater than or equal to 5 nm and less than or equal to 100 nm, for example.

The present invention is featured in that thickness of each upper bather layer 15A (not containing last upper barrier layer 15A′) forming an upper light-emitting layer is smaller than thickness of each lower barrier layer 13A forming a lower light-emitting layer. Thickness of each upper barrier layer 15A is smaller than thickness of each lower barrier layer 13A preferably by greater than or equal to 0.5 nm, more preferably by greater than or equal to 1 nm, and further preferably greater than or equal to 1.5 nm. As previously described, the larger the thickness of upper barrier layer 15A, the higher effect as a crystal recovery layer for recovering a crystal defect in upper well layer 15B is obtained. However, when upper barrier layer 15A is thick, it is expected that migration of an electron and a hole which are injected carriers in upper light-emitting layer 15 is interfered, and hence light emission by recombination between an electron and a hole tends to be hindered.

Thickness of last upper barrier layer 15A′ is preferably greater than or equal to 1 nm and less than or equal to 40 nm.

Thickness of each upper well layer 15B is further preferably, but not limited to, equal to thickness of each lower well layer 13B without limitation. An advantage is afforded when thickness of lower well layer 13B is equal to thickness of upper well layer 15B because light of the same wavelength is emitted in each well layer by recombination between an electron and a hole in each well layer, and hence the width of emission spectrum of nitride semiconductor light-emitting device 1 is narrowed. On the other hand, the width of emission spectrum of nitride semiconductor light-emitting device 1 can be widened by intentionally making thickness of upper well layer 15B differ from thickness of lower well layer 13B, or making thicknesses of well layers forming upper well layer 15B differ from each other.

Thickness of each upper well layer 15B is preferably greater than or equal to 1 nm and less than or equal to 7 nm. When thickness of each upper well layer 15B is outside this range, light emission efficiency tends to decrease.

N-type doping concentration in each upper barrier layer 15A is preferably, but not particularly limited to, less than or equal to 8×10¹⁷ cm⁻³. When n-type doping concentration in upper barrier layer 15A exceeds 8×10¹⁷ cm⁻³, a hole is less likely to be injected into upper light-emitting layer 15 when a voltage is applied to the light-emitting device, and hence decrease in light emission efficiency can be incurred. Each upper barrier layer 15A and last upper barrier layer 15A′ may contain a p-type dopant.

Composition of each upper well layer 15B is preferably adjusted in accordance with the emission wavelength required for the nitride semiconductor light-emitting device according to the present embodiment, and is, for example, preferably AlₐGa_{b}In_{(1-a-b)}N (0≦a<1, 0<b≦1), and more preferably an In_{c}Ga_{(1-c)}N (0<c<1) layer not containing Al. However, when ultraviolet emission, for example, at less than or equal to 375 nm is conducted, Al is generally contained as appropriate so as to widen the band gap. Also, it is preferred that each lower well layer 13B does not contain a dopant (a dopant material is not introduced at the time of growth) as much as possible. When each upper well layer 15B does not contain an n-type dopant, non-light-emitting recombination is less likely to occur in each upper well layer 15B, and excellent light emission efficiency is realized. Each upper well layer 15B may contain an n-type dopant, and as a result of this, a drive voltage of the light-emitting device tends to decrease.

<P-Type Nitride Semiconductor Layer>

In the constitution shown in FIG. 1, while the p-type nitride semiconductor layer has a triple layer structure made up of p-type AlGaN layer 16, p-type GaN layer 17, and high-concentration p-type GaN layer 18, this constitution is merely one example, and in general, p-type nitride semiconductor layers 16, 17, 18 are preferably, for example, an Alₛ₄Gaₜ₄Inᵤ₄N (0≦s4≦1, 0≦t4≦1, 0≦u4≦1, s4+t4+u4≠0) layer doped with a p-type dopant, and more preferably an Alₛ₄Ga₁₋ₛ₄N (0<s4≦0.4, preferably 0.1≦s4 ≦0.3) layer doped with a p-type dopant.

The p-type dopant is, for example, but not particularly limited to, magnesium.

Carrier concentration in p-type nitride semiconductor layers 17, 18 is preferably greater than or equal to 1×10¹⁷ cm⁻³. Here, since an activation ratio of the p-type dopant is about 0.01, p-type doping concentration (different from carrier concentration) in p-type nitride semiconductor layer 17, 18 is preferably greater than or equal to 1×10¹⁹ cm⁻³. However, p-type doping concentration in p-type nitride semiconductor layer 16 near upper light-emitting layer 15 may be lower than this.

Total thicknesses of p-type nitride semiconductor layers 16, 17 and 18 are preferably, but not particularly limited to, greater than or equal to 50 nm and less than or equal to 300 nm.

### <N-Side Electrode, Transparent Electrode, P-Side Electrode>

N-side electrode 21 and p-side electrode 25 are electrodes for supplying nitride semiconductor light-emitting device 1 with drive power. N-side electrode 21 and p-side electrode 25 include exclusively a pad electrode portion in FIG. 2 which is a plan view, however, an elongated protrusion (branch electrode) for current diffusion may be connected. Also under p-side electrode 25, an insulating layer for stopping injection of current may be provided, and by this, the quantity of light emission shielded by p-side electrode 25 is reduced. N-side electrode 21 is preferably made up of, for example, a titanium layer, an aluminum layer and a gold layer stacked in this order, and preferably has a thickness of about 1 μm on the assumption of the strength at the time of conducting wire bonding. P-side electrode 25 is preferably made up of, for example, a nickel layer, an aluminum layer, a titanium layer and a gold layer stacked in this order, and preferably has a thickness of about 1 μm. Compositions of n-side electrode 21 and p-side electrode 25 may be identical. Transparent electrode 23 is preferably a transparent conductive film of, for example, ITO (Indium Tin Oxide), or IZO (Indium Zinc Oxide), and preferably has a thickness of greater than or equal to 20 nm and less than or equal to 200 nm.

As described above, in nitride semiconductor light-emitting device 1 according to the present embodiment, thickness of upper barrier layer 15A in upper light-emitting layer 15 is smaller than thickness of lower barrier layer 13A in lower light-emitting layer 13. Therefore, it is possible to obtain the effects (i) piezoelectric field in upper well layer 15B of upper light-emitting layer 15 is reduced, and in association with this, light-emitting recombination probability increases, and (ii) diffusion of holes injected from p side into each upper well layer 15B is improved, and the density of injected holes can be decreased, and occurrence of Auger recombination is suppressed, and hence it is possible to prevent decrease in light emission efficiency.

This effect becomes significant when thickness of upper barrier layer 15A in upper light-emitting layer 15 is smaller than thickness of lower barrier layer 13A in lower light-emitting layer 13 by greater than or equal to 0.5 nm.

Also, in nitride semiconductor light-emitting device 1 according to the present embodiment, it is preferred that average n-type doping concentration of lower light-emitting layer 13 is higher than average n-type doping concentration of upper light-emitting layer 15. Therefore, it is possible to decrease a series resistance component in lower light-emitting layer 13, and to prevent rise in operation voltage even when nitride semiconductor light-emitting device 1 is driven at a large current.

As described above, in the present embodiment, since rise in operation voltage and decrease in light emission efficiency at the time of driving at a large current can be prevented, decrease in power efficiency at the time of driving at a large current can be prevented.

In nitride semiconductor light-emitting device 1 according to the present embodiment, thickness of lower barrier layer 13A is preferably equal to thickness of the layer directly under the same (lower barrier layer 13A situated on the side of n-type nitride semiconductor layer 9 with one layer of lower well layer 13B interposed therebetween with respect to lower barrier layer 13A of interest), or decreases toward p-type nitride semiconductor layer 16. As a result, the aforementioned effect (namely, the effect that deterioration in power efficiency at the time of driving at a great current can be prevented because rise in operation voltage and decrease in light emission efficiency at the time of driving at a large quantity can be prevented) becomes further significant. From a similar reason, thickness of upper barrier layer 15A is preferably equal to thickness of the layer directly under the same (upper barrier layer 15A situated on the side of n-type nitride semiconductor layer 9 with one layer of upper well layer 15B interposed therebetween with respect to upper barrier layer 15A of interest), or decreases toward p-type nitride semiconductor layer 16.

Further, in nitride semiconductor light-emitting device 1 according to the present embodiment, average n-type doping concentration of lower barrier layer 13A is preferably equal to average n-type doping concentration of the layer directly under the same, or decreases toward p-type nitride semiconductor layer 16. As a result, the effect of decreasing a series resistance component in lower light-emitting layer 13 becomes significant. From a similar reason, average n-type doping concentration of upper barrier layer 15A is preferably equal to average n-type doping concentration of the layer directly under the same, or decreases toward p-type nitride semiconductor layer 16.

A carrier concentration means a concentration of electron or hole, and is not determined only by an amount of the n-type dopant or an amount of the p-type dopant. In other words, the carrier concentration of lower light-emitting layer 13 is not determined only by an amount of the n-type dopant doped to lower light-emitting layer 13, and the carrier concentration of upper light-emitting layer 15 is not determined only by an amount of the n-type dopant doped to upper light-emitting layer 15. Such a carrier concentration is calculated according to a result of capacitance versus voltage characteristic of nitride semiconductor light-emitting device 1, and indicates the carrier concentration in the condition that a current is not injected, and is a sum of carriers generated from an ionized impurity, a crystal defect serving as a donor, or a crystal defect serving as an acceptor.

However, n-type carrier concentration can be regarded as being identical to n-type doping concentration because an activation ratio of Si or the like which is an n-type dopant is high. Also, n-type doping concentration can be easily determined by measuring concentration distribution in the depth direction by SIMS (Secondary Ion Mass Spectrometry). Further, relative relationship (ratio) of doping concentration is substantially the same with relative relationship (ratio) of carrier concentration. From these, in claims of the present invention, definition is made by doping concentration that is actually easy to be measured. Then, by averaging n-type doping concentrations obtained by measurement, it is possible to obtain average n-type doping concentration.

### EXAMPLE

In the following, examples of the present invention will be shown. The present invention is not limited to the examples as shown below.

### Example 1

First, a wafer formed from substrate 3 made of sapphire having an convexoconcave-worked upper face and a diameter of 100 mm was prepared, and on an upper face of the same, buffer layer 5 made of AlN was formed by sputtering.

Next, the wafer was introduced into a first MOCVD device, and base layer 7 made of undoped GaN was crystal-grown by a MOCVD method, using TMG (trimethyl gallium) and NH₃ as a source gas, and subsequently SiH₄ was added as a gas for dopant, to crystal-grow n-type nitride semiconductor layer 9 made of n-type GaN. At this time, thickness of base layer 7 was 4 μm, thickness of n-type nitride semiconductor layer 9 was 3 μm, and n-type doping concentration in n-type nitride semiconductor layer 9 was 6×10¹⁸ cm⁻³.

The wafer taken out of the first MOCVD device was introduced into a second MOCVD device, and the temperature of the wafer was set at 1050° C., and n-type nitride semiconductor layer 10 was crystal-grown. N-type nitride semiconductor layer 10 is made of an n-type GaN, and is 1.5 μm thick. Continuously, the temperature of the wafer was set at 880° C., and superlattice layer 11 was crystal-grown. Concretely, wide bandgap layer 11A made of Si-doped GaN and narrow bandgap layer 11B made of Si-doped InGaN were alternately crystal-grown periodically 20 times.

Here, as a source gas for wide bandgap layer 11A, TMG and NH₃ and SiH₄ were used. Thickness of each wide bandgap layer 11A was 1.75 nm, and n-type doping concentration in each wide bandgap layer 11A was 3×10¹⁸ cm⁻³.

Narrow bandgap layer 11B was crystal-grown by using TMG and TMI (trimethyl indium) and NH₃ and SiH₄ as a source gas. Thickness of each narrow bandgap layer 11B was 1.75 nm. Also, since the flow rate of TMI was adjusted so that wavelength of the light emitted by a well layer by photoluminescence was 375 nm, composition of each narrow bandgap layer was In_{y}Ga_{1-y}N (y=0.10). Average n-type doping concentration of superlattice layer 11 was about 3×10¹⁸ cm⁻³.

Then, the temperature of the wafer was lowered to 855° C., and lower light-emitting layer 13 was crystal-grown. Concretely, lower barrier layer 13A made of Si-doped GaN and lower well layer 13B made of undoped InGaN were alternately crystal-grown periodically three times.

Lower barrier layer 13A was crystal-grown by using TMG and NH₃ and SiH₄ as a source gas. A growth rate of each lower barrier layer 13A was set at 100 nm/hour. Thickness of each lower barrier layer 13A was 6.5 nm, n-type doping concentration in each lower barrier layer 13A was 3.4×10¹⁷ cm⁻³.

As lower well layer 13B, an undoped InₓGa₁₋ₓN layer (x=0.13) was crystal-grown using TMI gas and NH₃ gas as a source gas, and nitrogen gas as a carrier gas. A growth rate of each lower well layer 13B was set at 100 nm/hour. Thickness of each lower well layer 13B was 3.9 nm. Also, composition x of In was set by adjusting the flow rate of TMI so that wavelength of the light emitted by lower well layer 13B by photoluminescence was 448 nm. Average n-type doping concentration of lower light-emitting layer 13 including lower barrier layer 13A and lower well layer 13B was about 2.6×10¹⁷ cm⁻³.

Next, temperature of the wafer was decreased to 850° C. and upper light-emitting layer 15 was crystal-grown. Concretely, upper barrier layer 15A made of undoped GaN and upper well layer 15B made of undoped InGaN were alternately crystal-grown periodically three times.

Upper barrier layer 15A was crystal-grown using TMG and NH₃ and SiH₄ as a source gas. A growth rate of each upper barrier layer 15A was set at 100 nm/hour. Thickness of each upper barrier layer 15A was set at 4 nm, and was made smaller than thickness of each lower barrier layer 13A. Each upper barrier layer 15A was undoped.

As upper well layer 15B, an undoped InₓGa₁₋ₓN layer (x=0.13) was crystal-grown using TMI gas and NH₃ gas as a source gas and nitrogen gas as a carrier gas. A growth rate of each upper well layer 15B was set at 100 nm/hour. Thickness of each upper well layer 15B was set at 3.9 nm, and set to be the same thickness as thickness of each lower well layer 13B in design. Also, composition x of In was set by adjusting the flow rate of TMI so that wavelength of the light emitted by upper well layer 15B by photoluminescence was 448 nm. Average n-type doping concentration of upper light-emitting layer 15 including upper barrier layer 15A and upper well layer 15B was about 7×10¹⁶ cm⁻³.

Then, on the uppermost layer of upper well layers 15B, 10 nm of a last upper barrier layer 15A′ made of an undoped GaN layer was crystal-grown.

Then, the temperature of the wafer was raised, and on an upper face of uppermost barrier layer, p-type Al_{0.18}Ga_{0.82}N layer 16, p-type GaN layer 17 and p-type contact layer 18 were crystal-grown.

Then, p-type contact layer 18, p-type GaN layer 17, p-type AlGaN layer 16, upper light-emitting layer 15, lower light-emitting layer 13, superlattice layer 11, and n-type nitride semiconductor layer 10 were partly etched so that a part of n-type nitride semiconductor layer 10 was exposed. On an upper face of n-type nitride semiconductor layer 10 exposed by this etching, n-side electrode 21 made of Au was formed. Also, on an upper face of p-type contact layer 18, transparent electrode 23 made of ITO and p-side electrode 25 made of Au were sequentially formed. Also, transparent protection film 27 made of SiO₂ was formed so as to mainly cover transparent electrode 23 and the side face of each layer exposed by the aforementioned etching.

The wafer was split into chips of 280×550 μm in size, and a nitride semiconductor light-emitting device according to Example 1 was obtained.

The obtained nitride semiconductor light-emitting device was mounted on a TO-18 type stem, and light output was measured without conducting resin sealing, and light output of 45 mW (dominant wavelength 451 nm) was obtained at a drive current of 30 mA and a drive voltage of 2.9 V.

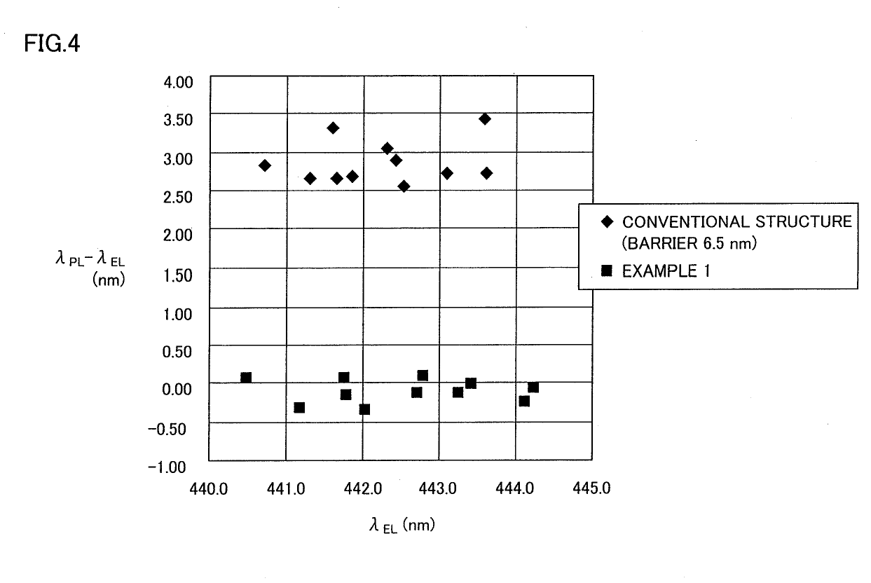

For the nitride semiconductor light-emitting device realizing high light emission efficiency in this manner, it was confirmed that a piezoelectric filed in a well layer was smaller than that in a conventional nitride semiconductor light-emitting device. Diminishment of piezoelectric field can be indirectly observed by a variety of methods. In one of such methods, difference between light emission peak wavelength λ_{PL} of photoluminescence and light emission peak wavelength λ_{EL} at the time of injection of current is compared, and when the difference is diminished, it can be determined that the piezoelectric field is diminished. As shown in FIG. 4 (in FIG. 4, relation between λ_{EL} and (λ_{PL}−λ_{EL}) in this example is shown), in the light-emitting device according to the present example, λ_{PL}−λ_{EL} is about −0.4 to +0.1 nm, and in the case of other design (every barrier layer thickness is 6.5 nm, “conventional structure” as shown in FIG. 4), λ_{PL}−λ_{EL} was 2.5 to 3.5 nm. As just described, in the light-emitting device according to the present example, λ_{PL}−λ_{EL} is considerably reduced in comparison with the other design described above. Also, from the fact that a variation in light emission wavelength was decreased at the time when the current density was changed by about 3 digits, it was determined that piezoelectric field was diminished.

### Example 2

In Example 2, the wafer diameter (diameter of substrate 3) was set at 150 mm, a MOCVD device different from that used in Example 1 was used, thickness of lower well layer 13B in lower light-emitting layer 13 was set at 3.25 nm, and thickness of lower barrier layer 13A was set at 6.25 nm. Further, thickness of upper well layer 15B in upper light-emitting layer 15 was set at 3.25 nm, and thickness of upper barrier layer 15A was set at 4 nm.

Although direct comparison cannot be made because the MOCVD device is different from that in Example 1, light output of 45 mW at a drive current of 30 mA was obtained also in the present example, and the light output was improved by about 1.5 mW compared with a conventional structure (the structure where thickness of barrier layer is identical in lower light-emitting layer 13 and upper light-emitting layer 15).

### Example 3

Example 3 is similar to Example 1 except that the number of layers of lower well layer 13B in lower light-emitting layer 13 was increased. In the following, difference from the aforementioned Example 1 is shown.

The number of layers of lower well layer 13B in lower light-emitting layer 13 is 6. N-type doping to lower well layer 13B and lower barrier layer 13A was conducted similarly to Example 1 including presence or absence of the same.

The number of layers of upper well layer 15B in upper light-emitting layer 15 is 3.

The obtained result was substantially equal to that in Example 1 within dispersion.

### Example 4

Example 4 is similar to Example 1 except that the number of layers of lower well layer 13B in lower light-emitting layer 13 and the number of layers of upper well layer 15B in upper light-emitting layer 15 were increased. In the following, difference from the aforementioned Example 1 will be shown.

The number of layers of lower well layer 13B in lower light-emitting layer 13 is 4. N-type doping to lower well layer 13B and lower barrier layer 13A was conducted similarly to Example 1 including presence or absence of the same.

The number of layers of upper well layer 15B in upper light-emitting layer 15 is 5.

In the obtained result, the drive voltage at a drive current of 30 mA was 2.95 V which was higher than that in Example 1 by 0.05 V.

### Example 5

In Example 5, based on Example 1, n-type doping is also conducted on upper barrier layer 15A (layer sandwiched between upper well layers 15B). Upper barrier layer 15A was doped so that n-type doping concentration was 3.4×10¹⁷ cm⁻³.

In the obtained result, the drive voltage at a drive current of 30 mA was 2.87 V which was lower than that in Example 1 by 0.03 V, however, it is suited for driving at a low current at a drive current of less than or equal to 30 mA because the light emission efficiency at a large current is decreased.

### Example 6

Based on Example 4, layer thicknesses of lower barrier layer 13A and upper barrier layer 15A were gradually varied. A sum of the number of layers of lower well layer and the number of layers of upper well layer is 9. The result of describing layer thicknesses of barrier layers from lower layer (on the side of substrate 3) without distinguishing between lower light-emitting layer 13 and upper light-emitting layer 15 is shown in Table 1.

TABLE 1

| Layer | Layer thickness |
|---|---|
| First barrier layer 0 | 6.5 nm |
| Barrier layer 1 | 6.5 nm |
| Barrier layer 2 | 6.5 nm |
| Barrier layer 3 | 6.0 nm |
| Barrier layer 4 | 5.5 nm |
| Barrier layer 5 | 5.0 nm |
| Barrier layer 6 | 4.5 nm |
| Barrier layer 7 | 4.0 nm |
| Barrier layer 8 | 4.0 nm |
| Last barrier layer 9 | 6.0 nm |

How to determine the border between lower light-emitting layer 13 and upper light-emitting layer 15 comes to an issue. Since an average of layer thickness of barrier layer 1 and layer thickness of barrier layer 8 is 5.25 nm, this value is taken as a border between lower light-emitting layer 13 and upper light-emitting layer 15, and barrier layer 1 to barrier layer 4 are regarded as lower barrier layer 13A, and barrier layer 5 to barrier layer 8 are classified into upper barrier layer 15A. This classification in the present example is given for convenience, and from the functional view point, the ratio between the function of lower light-emitting layer 13 and the function of upper light-emitting layer 15 changes little by little so that the proportion of lower light-emitting layer 13 is higher in lower layers, and proportion of upper light-emitting layer 15 is higher in upper layers.

First barrier layer 0, lower barrier layer 13A from barrier layer 1 to barrier layer 4 and lower well layer 13B between lower barrier layers 13A were doped so that n-type doping concentration was 3.4×10¹⁷ cm⁻³.

### Example 7

Based on Example 6, n-type doping concentration was also gradually varied. A sum of the number of layers of lower well layer and the number of layers of upper well layer is 9. The result of describing layer thicknesses and n-type doping concentrations of barrier layers from lower layer without distinguishing between lower light-emitting layer 13 and upper light-emitting layer 15 is shown in Table 2.

TABLE 2

| Layer | Layer thickness | N-type doping concentration |
|---|---|---|
| First barrier layer 0 | 6.5 nm | 3.4 × 10¹⁷ cm⁻³ |
| Barrier layer 1 | 6.5 nm | 3.0 × 10¹⁷ cm⁻³ |
| Barrier layer 2 | 6.5 nm | 2.5 × 10¹⁷ cm⁻³ |
| Barrier layer 3 | 6.0 nm | 2.0 × 10¹⁷ cm⁻³ |
| Barrier layer 4 | 5.5 nm | 1.5 × 10¹⁷ cm⁻³ |
| Barrier layer 5 | 5.0 nm | 1.0 × 10¹⁷ cm⁻³ |
| Barrier layer 6 | 4.5 nm | Undoped |
| Barrier layer 7 | 4.0 nm | Undoped |
| Barrier layer 8 | 4.0 nm | Undoped |
| Last barrier layer 9 | 6.0 nm | Undoped |

Similarly to Example 6, since an average of layer thickness of barrier layer 1 and layer thickness of barrier layer 8 is 5.25 nm, barrier layer 1 to barrier layer 4 are classified into lower barrier layer 13A, and barrier layer 5 to barrier layer 8 are classified into upper barrier layer 15A.

While embodiments and examples have been described above, it is originally planned to appropriately combine features of these embodiments and examples.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A nitride semiconductor light-emitting device comprising: an n-type nitride semiconductor layer, a lower light-emitting layer, an upper light-emitting layer, and a p-type nitride semiconductor layer in this order,
said lower light-emitting layer being formed by alternately stacking a plurality of lower well layers, and a lower barrier layer sandwiched between the lower well layers and having a large bandgap than the lower well layer,
said upper light-emitting layer being formed by alternately stacking a plurality of upper well layers, and an upper barrier layer sandwiched between the upper well layers and having a larger bandgap than the upper well layer, wherein
thickness of said upper barrier layer in said upper light-emitting layer is smaller than thickness of said lower barrier layer in said lower light-emitting layer.

2. The nitride semiconductor light-emitting device according to claim 1, wherein thickness of said upper barrier layer is smaller than thickness of said lower bather layer by greater than or equal to 0.5 nm.

3. The nitride semiconductor light-emitting device according to claim 1, wherein thickness of each layer of said lower barrier layer and said upper barrier layer is equal to thickness of a directly under layer, or decreases toward said p-type nitride semiconductor layer.

4. The nitride semiconductor light-emitting device according to claim 1, wherein average n-type doping concentration of said lower light-emitting layer is higher than average n-type doping concentration of said upper light-emitting layer.

5. The nitride semiconductor light-emitting device according to claim 4, wherein average n-type doping concentration of each layer of said lower barrier layer and said upper barrier layer is equal to average n-type doping concentration of a directly under layer, or decreases toward said p-type nitride semiconductor layer.
